(19) United States
(12) Patent Application Publication
(10) Pub. No.: US 2024/0332253 A1
(43) Pub. Date: Oct. 3, 2024

(54) SYSTEM ON CHIP INCLUDING INPUT AND OUTPUT CIRCUIT AND SEMICONDUCTOR DEVICE INCLUDING THE SAME

(71) Applicant: SAMSUNG ELECTRONICS CO., LTD., Suwon-si (KR)

(72) Inventors: KWANYEOB CHAE, Suwon-si (KR); Ji-Yeon Park, Suwon-si (KR)

(73) Assignee: SAMSUNG ELECTRONICS CO., LTD., Suwon-si (KR)

(21) Appl. No.: 18/532,742

(22) Filed: Dec. 7, 2023

(30) Foreign Application Priority Data
Mar. 29, 2023 (KR) 10-2023-0041487
May 20, 2023 (KR) 10-2023-0065924

(51) Int. Cl. H01L 25/065; H01L 23/00; H01L 23/538; H10B 80/00

(52) U.S. Cl. CPC H01L 25/0652; H01L 23/538; H01L 24/16; H10B 80/00; H01L 2224/16145; H01L 2224/16225; H01L 2924/1432; H01L 2924/1436

(57) ABSTRACT

A system on chip includes a processor and an input and output circuit including a plurality of input and output elements connected to the processor, wherein the plurality of input and output elements includes: a first input and output element spaced apart from the processor by a first distance; and a second input and output element spaced apart from the processor by a second distance, greater than the first distance, and connected to the processor by a first electrical path extending through a first region of the first input and output element, and wherein the first input and output element is connected to the processor by at least one first terminal provided in a second region that is separate from the first region.

### CROSS-REFERENCE TO RELATED APPLICATIONS

This application claims priority to Korean Patent Application No. 10-2023-0041487, filed on Mar. 29, 2023, and Korean Patent Application No. 10-2023-0065924, filed on May 22, 2023, in the Korean Intellectual Property Office, the disclosures of which are incorporated herein by reference in their entireties.

### BACKGROUND

The present disclosure relates to a system on chip (SoC) including an input/output circuit and a semiconductor device including the SoC.

With the development of electronic industry, electronic devices have been miniaturized and provided with multifunctionality. For example, there is increasing demand for miniaturization and multifunctionality of semiconductor devices for use in electronic devices. Accordingly, various technologies have been proposed to miniaturize semiconductor devices while increasing capacity of the signals processed by semiconductor devices to increase driving speed of semiconductor devices.

The number of input/output (I/O) elements should be increased in proportion to the number of signals processed by a semiconductor device to increase capacity of a signal processed by the semiconductor device. However, when the number of I/O elements provided in a semiconductor device is increased, a size of the semiconductor device may also be increased.

Accordingly, various methods of placing input/output elements have been proposed to increase capacity of a signal, processed by a semiconductor device, and to significantly reduce an increase in size of the semiconductor device.

### SUMMARY

One or more example embodiments provide a semiconductor device having a plurality of input/output elements provided to abut each other to have a significantly reduced area.

According to an aspect of an example embodiments, a system on chip includes: a processor; and an input and output circuit including a plurality of input and output elements connected to the processor, wherein the plurality of input and output elements includes: a first input and output element spaced apart from the processor by a first distance; and a second input and output element spaced apart from the processor by a second distance, greater than the first distance, and connected to the processor by a first electrical path extending through a first region of the first input and output element, and wherein the first input and output element is connected to the processor by at least one first terminal provided in a second region that is separate from the first region.

According to an aspect of an example embodiment, a semiconductor device includes: a system on chip including a plurality of input and output elements provided in a plurality of columns; and a memory mounted on an interposer and connected to the system on chip using the interposer, wherein the system on chip includes: a processor; a first input and output element provided in a first column spaced apart from the processor by a first distance; and a second input and output element adjacent to the first input and output element in a second column spaced apart from the processor by a second distance, greater than the first distance, and connected to the processor by a first electrical path extending through a first region of the first input and output element, and wherein the first input and output element is connected to the processor by at least one first terminal provided in a second region that is separate from the first region.

According to an aspect of an example embodiment, an input and output circuit includes a plurality of input and output elements, the plurality of input and output elements including: a first input and output element including at least one first terminal; and a second input and output element adjacent to the first input and output element, wherein the first input and output element includes: a first region including a first electrical path connected to the second input and output element; and a second region that is separate from the first region, the second region including the at least one first terminal, and wherein the second input and output element includes at least one second terminal provided at a point adjacent to the first region to be connected to the first electrical path.

### BRIEF DESCRIPTION OF THE DRAWINGS

The above and other aspects, features, and advantages will be more apparent from the following detailed description of one or more example embodiments, taken in conjunction with the accompanying drawings, in which:

FIG. 1A is a block diagram illustrating a configuration of a semiconductor device according to one or more example embodiments.

FIG. 1B is a cross-sectional view of a semiconductor device according to one or more example embodiments.

FIG. 2 is a plan view of a system on chip in the semiconductor device of FIG. 1A, according to one or more example embodiments.

FIG. 3 is an enlarged view of region “A” in a configuration of the system on chip illustrated in FIG. 2, according to one or more example embodiments.

FIG. 4A is a diagram illustrating a configuration of a first input/output element of FIG. 3, according to one or more example embodiments.

FIG. 4B is a diagram illustrating a configuration of a second input/output element of FIG. 3, according to one or more example embodiments.

FIG. 5 is across-sectional view of the first input/output element of FIG. 4A, taken along line B-B′, according to one or more example embodiments.

FIG. 6A is a cross-sectional view of a semiconductor device according to one or more example embodiments.

FIG. 6B is a plan view of a system on chip of FIG. 6A.

### DETAILED DESCRIPTION

Hereinafter, example embodiments will be described with reference to the accompanying drawings. The same reference numerals are used for the same components in the drawings, and duplicate descriptions thereof are omitted.

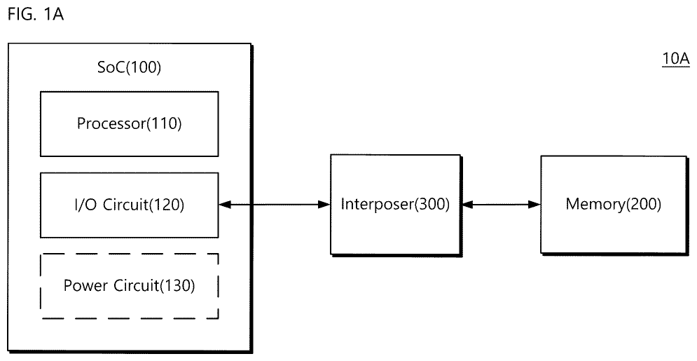

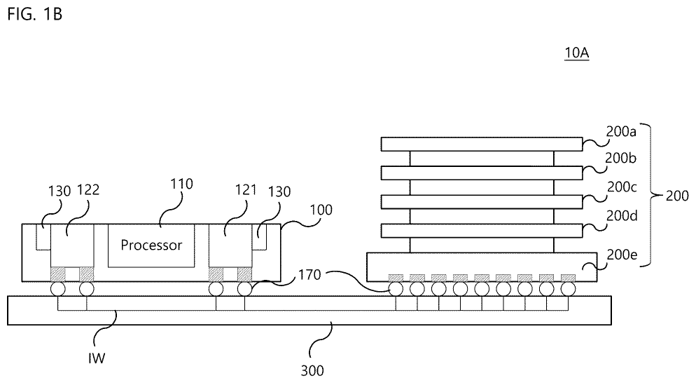

FIG. 1A is a block diagram illustrating a configuration of a semiconductor device according to one or more example embodiments. FIG. 1B is a cross-sectional view of a semiconductor device 10A according to one or more example embodiments.

Referring to FIG. 1A, a semiconductor device 10A according to one or more example embodiments may include a system on chip (SoC) 100 and a memory 200.

Referring to FIG. 1b, the system on chip 100 and the memory 200 may be mounted on an interposer 300. For example, the system on chip 100 and the memory 200 may be mounted on the interposer 300 using a plurality of bumps 170.

According to one or more example embodiments, the system on chip 100 and the memory 200 according to one or more example embodiments may be mounted on a first surface of the interposer 300. According to one or more example embodiments, the system on chip 100 may be mounted on a first surface of the interposer 300, and the memory 200 may be mounted on a second surface of the interposer 300, wherein the second surface is parallel to the first surface.

Furthermore, the system on chip 100 and the memory 200 may be connected to each other through the interposer 300.

The system on chip 100 may execute applications, supported by the semiconductor device 10A, using the memory 200. Accordingly, the system on chip 100 may also be referred to as a host, an application processor (AP), or the like.

According to one or more example embodiments, the system on chip 100 may include a processor 110 which may control the overall operation of the semiconductor device 10A. The processor 110 may control the memory 200, and may input and output data to and from the memory 200. For example, the processor 110 may access the memory 200 in a direct memory access (DMA) scheme.

The system on chip 100 may include an input/output (I/O) circuit 120 electrically connected to the memory 200 and the processor 110. The input/output circuit 120 may transmit a data signal from the processor 110 to the memory 200 through the interposer 300. For example, the input/output circuit 120 may transmit at least one of a command, an address, a clock, or other control signals to the memory 200 through the interposer 300. Also, the input/output circuit 120 may receive a data signal from the memory 200 through the interposer 300.

Referring to FIG. 1B, the input/output circuit 120 may include a plurality of input/output circuits 121 and 122 spaced apart from each other with the processor 110 between the input/output circuits 121 and 122. For example, the input/output circuit 120 may include a first input/output circuit 121 and a second input/output circuit 122 provided to be symmetrical with respect to the processor 110.

Accordingly, the processor 110 may transmit and receive data signals to and from the memory 200 through at least a portion of the first input/output circuit 121 and the second input/output circuit 122.

As described above, the system on chip 100 according to one or more example embodiments may transmit and receive signals to and from the memory 200 through the plurality of input/output circuits 121 and 122, which are spaced apart from each other around the processor 110.

Thus, the semiconductor device 10A according to one or more example embodiments may significantly reduce an increase in size of the system on the chip 100 caused by the input/output circuit 120. As a result, the semiconductor device 10A according to one or more example embodiments may significantly reduce an area of the system on chip 100.

Also, the memory 200 may be electrically connected to the input/output circuit 120 of the system on chip 100 through the interposer 300. The memory 200 may receive a data signal or transmit a data signal through the interposer 300. Also, the memory 200 may receive at least one of a command, an address, a clock, or other control signals through the interposer 300.

According to one or more example embodiments, the interposer 300 may include a path (or a bus) through which data signals may be transmitted. For example, the interposer 300 may include at least one internal wiring IW connecting the system on chip 100 and the memory 200 to each other.

Referring to FIG. 1B, a memory 200 according to one or more example embodiments may include a buffer die 200e and a plurality of memory chips 200a, 200b, 200c, and 200d. For example, the memory 200 may include a buffer die 200e provided on the interposer 300 and a plurality of memory chips 200a, 200b, 200c, and 200d stacked on the buffer die 200e.

Thus, the memory 200 may be referenced as a high bandwidth memory (HBM) including the plurality of memory chips 200a, 200b, 200c, and 200d stacked on the buffer die 200e. The plurality of memory chips 200a, 200b, 200c, and 200d may be referred to as HBM DRAM elements.

According to one or more example embodiments, the memory 200 includes a volatile memory device such as a static random access memory (SRAM) device, or a nonvolatile memory device such as a phase-change random access memory (PRAM) device, a magnetoresistive random access memory (MRAM) device, or a ferroelectric random access memory (FeRAM) device, or a resistive random access memory (RRAM) device.

Hereinafter, the memory 200 according to one or more example embodiments will be described as being an HBM.

In addition, it will be apparent that the system on chip 100 and the memory 200 provided on the interposer 300 have a chiplet structure. For example, the system on chip 100 and the memory 200 provided on the interposer 300 may be chips (or intellectual properties (IPs)), each designed to perform a designated function.

For example, the system on chip 100 may be a central processing unit (CPU) chip or an input/output circuit chip.

According to one or more example embodiments, the interposer 300 may be formed of, for example, silicon, but one or more example embodiments are not limited thereto.

The system on chip 100 may further include a power circuit 130 supplying power to at least a portion of the processor 110 and the input/output circuit 120. According to one or more example embodiments, the power circuit 130 may be provided adjacent to the input/output circuit 120 on the system on chip 100. According to one or more example embodiments, the power circuit 130 may be referred to as a power management integrated circuit (PMIC).

According to one or more example embodiments, at least a portion of the processor 110, the input/output circuit 120, and the power circuit 130 may be provided on one surface of the system on chip 100, but one or more example embodiments are not limited thereto.

According to one or more example embodiments, at least a portion of the processor 110, the input/output circuit 120, and the power circuit 130 may be implemented in an internal layer of the system on chip 100.

According to one or more example embodiments, the power circuit 130 may be provided as a component, separate from the system on chip 100. For example, the power circuit 130 may be provided on another surface of the interposer 300, parallel to one surface on which the system on chip 100 and the memory 200 are provided. As another example, the power circuit 130 may be provided on one surface of a printed circuit board or a mother board connected to the interposer 300.

However, the disposition of the power circuit 130 is not limited to the above one or more example embodiments, and it will be apparent that the power circuit 130 may be at various dispositions electrically connected to the system on chip 100 and the memory 200.

Referring to the above-described configuration, the semiconductor device 10A according to one or more example embodiments, may perform signal transfer between the processor 110 and the memory 200 through the input/output circuit 120 provided in the system on chip 100. According to one or more example embodiments, the input/output circuit 120 may include a plurality of input/output circuits 121 and 122 provided to be spaced apart from each other.

Thus, the semiconductor device 10A according to one or more example embodiments may increase the degree of integration of the system on chip 100. Also, the semiconductor device 10A may significantly reduce the area of the system on chip 100.

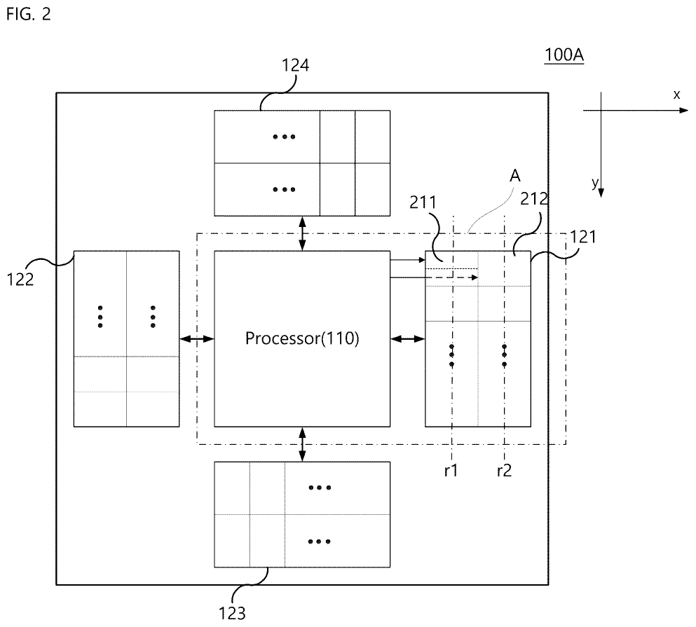

FIG. 2 is a plan view of a system on chip 100A in the semiconductor device of FIG. 1a.

Referring to FIG. 2, a system on chip 100A according to one or more example embodiments may include a processor 110 and a plurality of input/output circuits 121, 122, 123, and 124, which are electrically connected to the processor 110. According to one or more example embodiments, the system on chip 100A and a configuration thereof may be referenced as an example of the system on chip 100 of FIG. 1a and the configuration thereof, according to one or more example embodiments.

For example, the system on chip 100A may include a first input/output circuit 121, a second input/output circuit 122, a third input/output circuit 123, and a fourth input/output circuit 124 spaced apart from each other around the processor 110.

For example, the system on chip 100A may include the processor 110 provided in a center of the system on chip 100A. In addition, the system on chip 100A may include a first input/output circuit 121 and a second input/output circuit 122, which are provided to be symmetrical with respect to the processor 110. In addition, the system on chip 100A may include a third input/output circuit 123 and a fourth input/output circuit 124, which are provided to be symmetrical with respect to the processor 110.

For example, the plurality of input/output circuits 121, 122, 123, and 124 may be provided to surround the processor 110.

However, the dispositions of the processor 110 and the plurality of input/output circuits 121, 122, 123, and 124 on the system on chip 100A are not limited to the above one or more example embodiments. For example, according to one or more example embodiments, at least one of the plurality of input/output circuits 121, 122, 123, and 124 may be omitted, or an additional input/output circuit may be provided.

According to one or more example embodiments, each of the plurality of input/output circuits 121, 122, 123, and 124 may include a plurality of input/output elements connected to the processor 110. For example, each of the plurality of input/output circuits 121, 122, 123, and 124 may include a plurality of input/output elements arranged in a plurality of columns to be connected to the processor 110.

For example, the first input/output circuit 121 may include a first input/output element 211 provided in a first column r1 spaced apart from the processor 110 by a first distance. Also, the first input/output circuit 121 may include a second input/output element 212 provided in a second column r2 spaced apart from the processor 110 by a second distance, greater than the first distance.

Among the plurality of input/output elements included in the first input/output circuit 121, input/output elements provided in the second column r2 may be connected to the processor 110 through a region of input/output elements provided in the first column r1.

For example, the second input/output element 212 provided in the second column r2 may be connected to the processor 110 through an electrical path passing through a region of the first input/output element 211 provided in the first column r1.

Thus, the first input/output device 211 and the second input/output device 212 may be provided to abut each other without a gap. Furthermore, a plurality of input/output elements included in each of the plurality of input/output circuits 121, 122, 123, and 124 may be provided to abut each other without a gap.

According to the above-described configuration, the semiconductor device 10A according to one or more example embodiments may significantly reduce an area of the system on chip 100A while maintaining the capacity of signals input and output by the system on chip 100A.

Also, the plurality of input/output elements included in each of the plurality of input/output circuits 121, 122, 123, and 124 may be connected to the processor 110 through a straight path.

For example, among a plurality of input/output elements included in the first input/output circuit 121, input/output elements provided in the second column r2 may be connected to the processor 110 through an electrical path passing through a region of input/output elements provided in the first column r1.

Accordingly, the semiconductor device 10A according to one or more example embodiments may reduce, and may prevent, signal deterioration caused by a detour of an electrical path connecting the processor 110 and the input/output elements.

In addition, the semiconductor device 10A may significantly reduce an increase in area of the system on chip 100A, caused by an arrangement of an electrical path connecting the processor 110 and the input/output elements to each other.

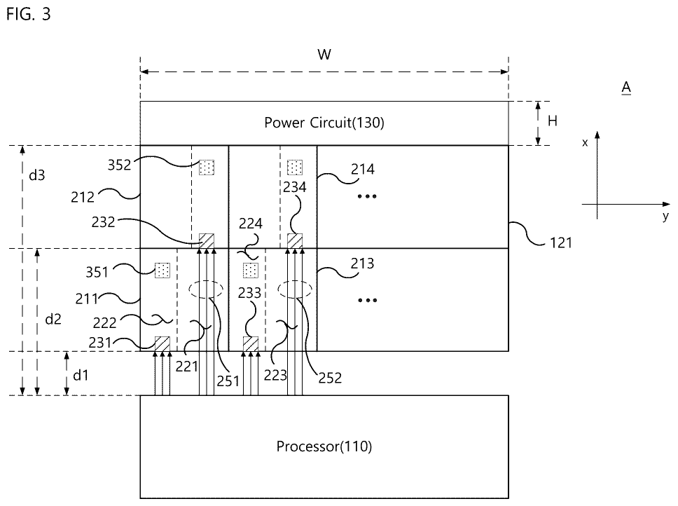

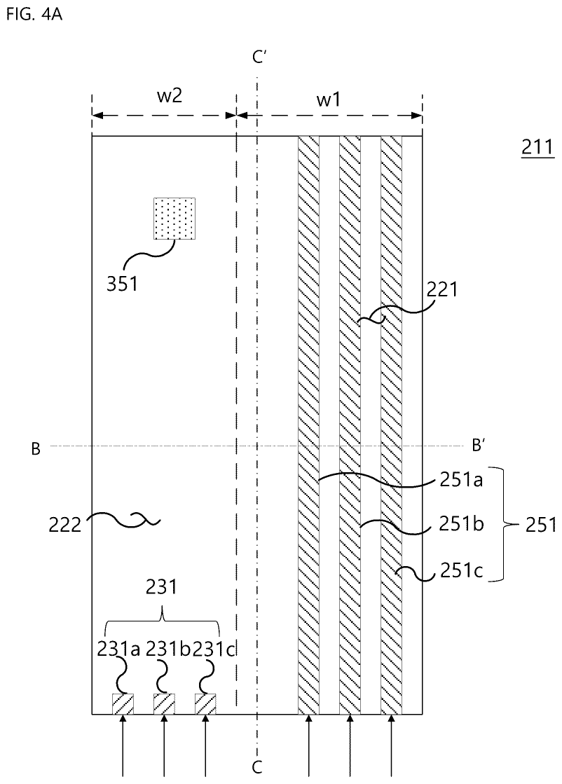

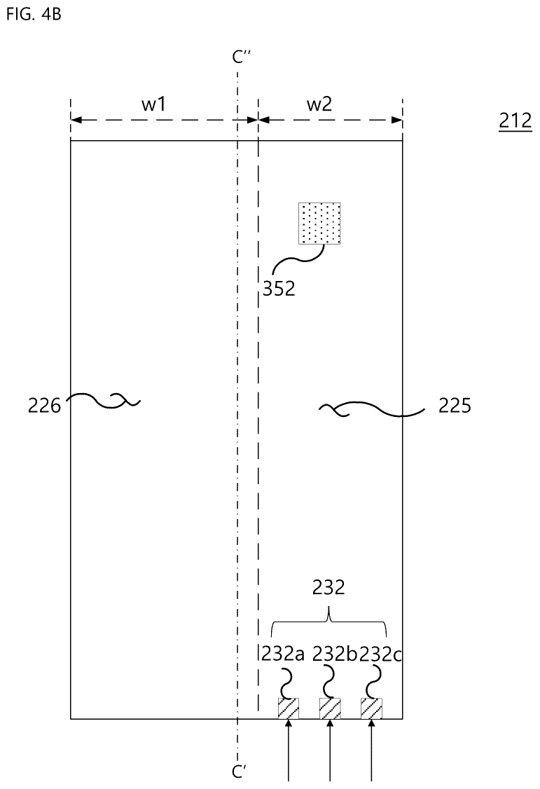

FIG. 3 is an enlarged view of region “A” in a configuration of the system on chip illustrated in FIG. 2, according to one or more example embodiments. FIG. 4a is a diagram illustrating a configuration of a first input/output element of FIG. 3, according to one or more example embodiments. FIG. 4b is a diagram illustrating a configuration of a second input/output element of FIG. 3, according to one or more example embodiments.

Referring to FIG. 3, a system on chip 100A according to one or more example embodiments may include a processor 110, a first input/output circuit 121 connected to the processor 110, and a power circuit 130.

According to one or more example embodiments, the first input/output circuit 121 may include a plurality of input/output elements 211, 212, 213, and 214, each connected to the processor 110.

For example, the first input/output circuit 121 may include a first input/output element 211 and a third input/output element 213 spaced apart from the processor 110 by a first distance d1. According to one or more example embodiments, the first input/output element 211 and the third input/output element 213 may have substantially the same structure.

In addition, the first input/output circuit 121 may include a second input/output element 212 and a fourth input/output element 214 provided to be apart from the processor 110 by a second distance d2, greater than the first distance d1. According to one or more example embodiments, the second input/output element 212 and the fourth input/output element 214 may have substantially the same structure.

According to one or more example embodiments, the plurality of input/output elements 211, 212, 213, and 214 may be provided to abut each other without a gap. For example, the second input/output element 212 may be provided adjacent to the first input/output element 211. Also, the third input/output element 213 may be provided adjacent to the first input/output element 211. Also, the fourth input/output element 214 may be provided adjacent to the second input/output element 212 and the third input/output element 213.

The second input/output element 212 may be connected to the processor 110 through a first electrical path 251 passing through a region of the first input/output element 211. For example, the second input/output element 212 may be connected to the processor 110 through a first electrical path 251 passing through the first region 221 of the first input/output element 211.

For example, the first electrical path 251 connecting the second input/output element 212 and the processor 110 to each other may be provided through the first region 221 of the first input/output element 211. The first region 221 may include a first electrical path 251 connecting the second input/output element 212 and the processor 110 to each other.

As described above, the second input/output element 212 may be connected to the processor 110 through the first electrical path 251 passing through the first region 221 of the first input/output element 211 in a state of being provided to abut the first input/output element 211 without a gap.

The fourth input/output element 214 may be connected to the processor 110 through a second electrical path 252 passing through a region of the third input/output element 213. For example, the fourth input/output element 214 may be connected to the processor 110 through the second electrical path 252 passing through the third region 223 of the third input/output element 213.

For example, the second electrical path 252 connecting the fourth input/output element 214 and the processor 110 to each other may be provided through the third region 223 of the third input/output element 213.

As described above, the fourth input/output element 214 may be connected to the processor 110 through the second electrical path 252 passing through the third region 223 of the third input/output element 213 in a state of being provided to abut the third input/output element 213 without a gap.

Accordingly, the first input/output circuit 121 may include input/output elements (for example, the first input/output element 211 and the second input/output element 212) spaced apart from the processor 110 by different distances d1 and d2 and may abut each other.

Thus, the first input/output circuit 121 according to one or more example embodiments may have a significantly reduced area. In addition, the semiconductor device 10A according to one or more example embodiments may improve the degree of integration of the system on chip 100A.

According to one or more example embodiments, the third input/output element 213 may be spaced apart from the processor 110 by the first distance d1 and may abut the first input/output element 211 without a gap. For example, the third input/output element 213 may abut the first input/output element 211 without a gap in the first column r1 spaced apart from the processor 110 by the first distance d1.

Because the first electrical path 251 is provided through the first region 221 of the first input/output elements 211, the third input/output element 213 may abut the first input/output element 211 without a gap.

The fourth input/output element 214 may be spaced apart from the processor 110 by a second distance d2 to be provided adjacent to the second input/output element 212 and the third input/output element 213. For example, the fourth input/output element 214 may be provided to abut the second input/output element 212 and the third input/output element 213 without a gap in the second column r2 spaced apart from the processor 110 by the second distance d2.

For example, the first input/output circuit 121 may include input/output elements (for example, the first input/output element 211 and the third input/output element 213) spaced apart from the processor 110 by the same distance (for example, d1 or d2) to be provided adjacent to each other.

Through the above configuration, the first input/output circuit 121 according to one or more example embodiments may have a significantly reduced area. In addition, the semiconductor device 10A according to one or more example embodiments may improve the degree of integration of the system on chip 100A.

The system on chip 100A may further include a power circuit 130 supplying power to at least a portion of the processor 110 and the first input/output circuit 121.

According to one or more example embodiments, the power circuit 130 may be adjacent to one surface of the first input/output circuit 121. For example, the power circuit 130 may be spaced apart from the processor 110 by a third distance d3 and may be provided adjacent to the first input/output circuit 121.

The power circuit 130 may be provided adjacent to a second edge, parallel to a first edge adjacent to the processor 110, of the first input/output circuits 121.

According to one or more example embodiments, the power circuit 130 may have the same width W as the width W of the first input/output circuit 121. Furthermore, the power circuit 130 may have a shape of a rectangle having a width W, greater than a height H thereof.

However, the disposition and shape of the power circuit 130 is not limited to the above-described one or more example embodiments.

As described above, the system on chip 100A according to one or more example embodiments may have the same width W as that of the first input/output circuit 121, and may include the power circuit 130 provided adjacent to one surface of the first input/output circuit 121.

Thus, the semiconductor device 10A according to one or more example embodiments may significantly reduce an increase in area of the system on chip 100A, caused by the power circuit 130. As a result, the system on chip 100A according to one or more example embodiments may have a significantly reduced area.

Referring to FIGS. 3 and 4A, the first input/output element 211 may include at least one first terminal 231 provided in a second region 222, separate from the first region 221. For example, the first input/output element 211 may include a 1-1-th terminal 231a, a 1-2-th terminal 231b, and a 1-3-th terminal 231c provided in the second region 222.

Furthermore, the first input/output element 211 may be connected to the processor 110 through the at least one first terminal 231 provided in the second region 222. For example, the first input/output element 211 may be connected to the processor 110 through an electrical path provided along a straight line directed from the processor 110 toward the at least one first terminal 231.

Referring to FIGS. 3 and 4B together, the second input/output element 212 may include at least one second terminal 232 provided in a portion adjacent to the first region 221 of the first input/output element 211. For example, the second input/output element 212 may include a 2-1-th terminal 232a, a 2-2-th terminal 232b, and a 2-3-th terminal 232c provided in the fifth region 225 adjacent to the first region 221 of the first input/output element 211.

The second input/output element 212 may be connected to the processor 110 through a first electrical path 251 connected from the processor 110 to the at least one second terminal 232 through the first region 221 of the first input/output element 211.

For example, the first electrical path 251 may include a 1-1-th electrical path 251a connected to the 2-1-th terminal 232a, a 1-2-th electrical path 251b connected to the 2-2-th terminal 232b, and a 1-3-th electrical path 251c connected to the 2-3-th terminal 232c.

According to one or more example embodiments, the electrical paths 251a, 251b, and 251c may be referenced as internal wirings provided in the first region 221 of the first input/output element 211.

However, the number or configuration of the first electrical path 251 provided through the first region 221 of the first input/output element 211 is not limited to the above one or more example embodiments.

According to one or more example embodiments, the first electrical path 251 may be provided as a straight line connected to the at least one second terminal 232 from the processor 110 through the first region 221. The first electrical path 251 may be provided along a virtual straight line connected from the processor 110 to the at least one second terminal 232 through the first region 221.

For example, the 1-1-th electrical path 251a may be provided as a straight line directed from the processor 110 toward the 2-1-th terminal 232a through the first region 221.

The third input/output element 213 may include at least one third terminal 233 provided in a fourth region 224, separate from the third region 223. Furthermore, the third input/output element 213 may be connected to the processor 110 through the at least one third terminal 233 provided in the fourth region 224. For example, the third input/output element 213 may be connected to the processor 110 through an electrical path provided along a straight line directed from the processor 110 toward the at least one third terminal 233 provided in the fourth region 224.

Also, the fourth input/output element 214 may include at least one fourth terminal 234 provided in a portion adjacent to the third region 223 of the third input/output element 213.

The fourth input/output element 214 may be connected to the processor 110 through a second electrical path 252 connected from the processor 110 to the at least one fourth terminal 234 through the third region 223 of the third input/output element 213.

According to one or more example embodiments, the second electrical path 252 may be provided as a straight line connected from the processor 110 to the at least one fourth terminal 234 through the third region 223. For example, the second electrical path 252 may be provided along a virtual straight line connecting the processor 110 to the at least one fourth terminal 234 through the third region 223.

As described above, each of the plurality of input/output elements included in the first input/output circuit 121 may be connected to the processor 110 through an electrical path having a shape of a straight line.

Thus, the first input/output circuit 121 according to one or more example embodiments may prevent a signal from deteriorating due to detouring of an electrical path connecting the processor 110 and the input/output elements to each other.

In addition, the semiconductor device 10A according to one or more example embodiments may significantly reduce an increase in area of the system on chip 100A, caused by a wiring connecting the input/output element and the processor 110 to each other.

Referring to FIGS. 4A and 4B together, the first input/output element 211 and the second input/output element 212 may have a symmetrical structure.

For example, the first input/output element 211 and the second input/output element 212 may have a structure symmetrical with respect to a virtual reference line C-C′-C″ crossing a center of the first input/output element 211 and a center of the second input/output element 212.

According to one or more example embodiments, the at least one first terminal 231 and the at least one second terminal 232 may be provided to be symmetrical with respect to the virtual reference line C-C′-C″ crossing the center of the first input/output element 211 and the center of the second input/output element 212. For example, the 1-1-th terminal 231a and the 2-3-th terminal 232c may be provided to be symmetrical with respect to a virtual reference line C-C′-C″ crossing the center of the first input/output element 211 and the center of the second input/output element 212.

The first region 221 and the sixth region 226 may be provided to be symmetrical with respect to the virtual reference line C-C′-C″ crossing the center of the first input/output element 211 and the center of the second input/output element 212. For example, the first region 221 may be provided to have a first width w1 on one side of the virtual reference line C-C′-C″, and the sixth region 226 may be provided to have the first width w1 on the other side of the virtual reference line C-C′-C″.

In addition, the second region 222 and the fifth region 225 may be provided to be symmetrical with respect to the virtual reference line C-C′-C″ crossing the center of the first input/output element 211 and the center of the second input/output element 212. For example, the second region 222 may be provided to have a second width w2 on one side of the virtual reference line C-C′-C″, and the fifth region 225 provided to have the second width w2 on the other side of the line C-C′-C″.

Each of the second region 222 and the fifth region 225 may have a second width w2, smaller than or equal to the first width w1 of each of the first region 221 and the sixth region 226.

The sixth region 226 of the second input/output element 212 may further include an electrical path passing across the sixth region 226.

For example, each of the first input/output element 211 and the second input/output element 212 may be understood to have a vertically inverted shape with respect to the virtual reference line C-C′-C″.

Similarly, each of the third input/output element 213 and the fourth input/output element 214 may have a structure symmetrical with respect to a virtual reference line crossing the center of the third input/output element 213 and the center of the fourth input/output element 214.

As described above, among the first input/output circuits 121 according to one or more example embodiments, the input/output elements spaced apart from the processor 110 by the first distance d1 and the input/output elements spaced apart from the processor 110 by the second distance d2 may have shapes corresponding to each other.

For example, the semiconductor device 10A according to one or more example embodiments may include an input/output circuit in which a plurality of input/output elements having the same shape are provided to be symmetrical with each other. Thus, the semiconductor device 10A according to one or more example embodiments may reduce costs required to implement an input/output circuit.

Referring to FIGS. 4A and 4B together, the first input/output element 211 may include a first contact 351 connected to an interposer 300 (or a bump pad). In addition, the second input/output element 212 may include a second contact 352 connected to the interposer 300. According to one or more example embodiments, the first contact 351 and the second contact 352 may be referenced as an LB neck.

The first contact 351 may be provided in the second region 222, and the second contact 352 may be provided in the fifth region 225.

The first input/output element 211 may output a signal, received through the at least one first terminal 231, through the first contact 351. For example, the first input/output element 211 may output a signal, received from the processor 110, through at least one first terminal 231, to the memory 200 through the first contact 351.

Also, the first input/output element 211 may transmit a signal, received through the first contact 351, to the processor 110 through the at least one first terminal 231. For example, the first input/output element 211 may transmit a signal, received from the memory 200 through the first contact 351, to the processor 110, through the at least one first terminal 231.

According to the above-described configuration, the first input/output element 211 according to one or more example embodiments may perform signal input and output operations between the processor 110 and the memory 200 using the at least one first terminal 231 and the first contact 351.

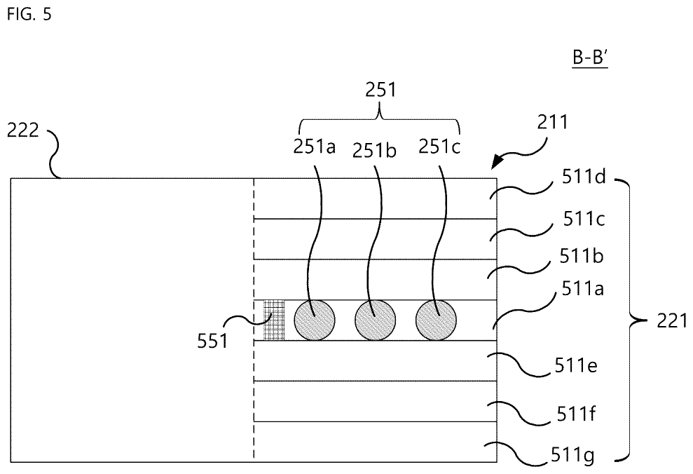

FIG. 5 is a cross-sectional view of the first input/output element of FIG. 4a, taken along line B-B′, according to one or more example embodiments.

Referring to FIG. 5, the first electrical path 251 according to one or more example embodiments may be provided to pass through a first layer 511a, among a plurality of layers included in the first region 221 of the first input/output element 211.

For example, the first region 221 of the first input/output element 211 may include a plurality of layers 511a, 511b, 511c, 511d, 511e, 511f, and 511g. According to one or more example embodiments, the first electrical path 251 may be provided to pass through the first layer 511a, among the plurality of layers 511a, 511b, 511c, 511d, 511e, 511f, and 511g of the first region 221.

Accordingly, the second input/output element 212 may be connected to the processor 110 through the first electrical path 251 passing through the first layer 511a, among the plurality of layers 511a, 511b, 511c, 511d, 511e, 511f, and 511g of the first region 221.

For example, the second input/output element 212 may be connected to the processor 110 through the first electrical path 251 passing through the first layer 511a of the first region 221 of the first input/output element 211.

Through the above-described configuration, a plurality of input/output elements including the first input/output element 211 and the second input/output element 212 may be provided to abut each other without a gap.

Accordingly, the semiconductor device 10A according to one or more example embodiments may improve the degree of integration of the input/output circuits 121, 122, 123, and 124.

According to one or more example embodiments, the plurality of layers 511a, 511b, 511c, 511d, 511e, 511f, and 511g of the first region 221 may be electrically connected to each other through a conductive via 551. For example, the first input/output element 211 may include a conductive via 551 penetrating through the first layer 511a of the first region 221.

The second layer 511b and the fifth layer 511e may be electrically connected to each other through the conductive via 551 penetrating the first layer 511a. Thus, a wiring (or an element) provided on the second layer 511b and a wiring provided on the fifth layer 511e may be electrically connected to each other.

According to the above-described configuration, the first electrical path 251 may be provided in at least a portion of the first layer 511a of the first region 221, and the conductive via 551 may be provided in another portion thereof. For example, the first layer 511a may include an electrical configuration for the operation of the first input/output element 211, other than the first electrical path 251.

As described above, in the input/output element according to one or more example embodiments, a portion of the first region 221 excluding a portion in which an electrical path is provided may be utilized to dispose a wiring or an element for input/output operations of signals.

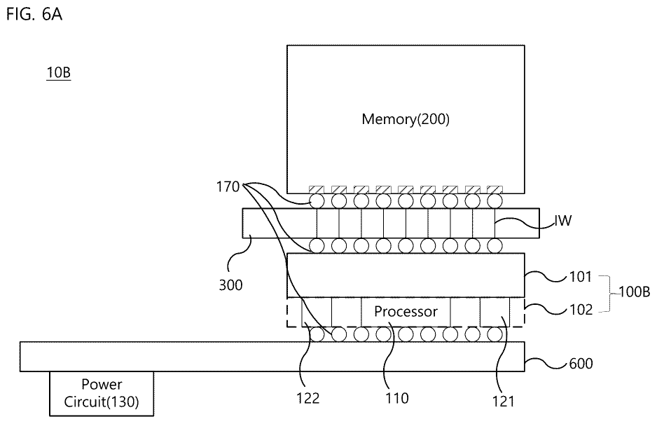

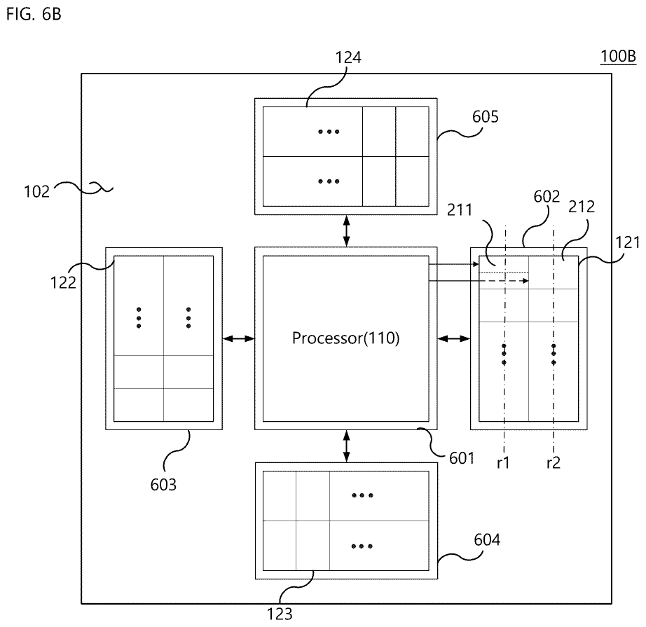

FIG. 6A is a cross-sectional view of a semiconductor device 10B according to one or more example embodiments, and FIG. 6b is a plan view of a system on chip 100B of FIG. 6a, according to one or more example embodiments.

Referring to FIG. 6A, a semiconductor device 10B according to one or more example embodiments may include a system on chip 100B and a memory 200 provided on a printed circuit board 600 and connected to each other through an interposer 300. Referring to FIG. 6B, the system on chip 100B according to one or more example embodiments may include a processor 110 and a plurality of input/output circuits 121, 122, 123, and 124, respectively provided on a plurality of dies 601, 602, 603, 604 and 605.

According to one or more example embodiments, the semiconductor device 10B and the system on chip 100B of FIGS. 6A and 6B may be understood as examples of the semiconductor device 10A and the system on chip 100 of FIG. 1a, respectively. Therefore, the same or substantially the same components as the above-described components are denoted by the same reference numerals, and redundant descriptions thereof will be omitted.

According to one or more example embodiments, the system on chip 100B and the memory 200 may be mounted on different surfaces of the interposer 300, respectively. For example, the system on chip 100B may be mounted on one surface of the interposer 300, and the memory 200 may be mounted on the other surface of the interposer 300, parallel to the surface on which the system on chip 100B is mounted.

According to one or more example embodiments, for example, the interposer 300 may be formed of silicon, but one or more example embodiments are not limited thereto.

The system on chip 100B and the memory 200 may be connected to the interposer 300 through a plurality of bumps 170. Furthermore, the system on chip 100B and the memory 200 may be electrically connected to each other through an internal wiring IW provided in the interposer 300.

The semiconductor device 10B may include a power circuit 130 provided on one surface of the printed circuit board 600. For example, the power circuit 130 may be mounted on a surface of the printed circuit board 600, parallel to the surface on which the system on chip 100B is mounted. For another example, the power circuit 130 may be provided on one surface of the interposer 300.

However, the disposition of the power circuit 130 is not limited to the above one or more example embodiments, and may be at various dispositions in which the power circuit 130 is electrically connected to the system on chip 100 and the memory 200.

According to one or more example embodiments, the system on chip 100B and the memory 200 mounted on the interposer 300 may have a chiplet structure. For example, the system on chip 100B provided on the interposer 300 may include chips (or intellectual properties (IPs)) designed to perform respective designated functions thereof.

Referring to FIGS. 6A and 6B, the system on chip 100B may include a substrate 101 and an active layer 102. Furthermore, the system on chip 100B may include a processor 110 and a plurality of input/output circuits 121 and 122 designed to perform respective functions thereof and provided on the active layer 102.

For example, referring to FIG. 6B, the system on chip 100B may include a processor 110 and a plurality of input/output circuits 121, 122, 123, and 124 designed to perform respective functions thereof and mounted on a plurality of dies 601, 602, 603, 604 and 605 on the active layer 102.

The system on chip 100B may include a processor 110 designed to control the overall operation of the semiconductor device 10B and may be provided on the first die 601. According to one or more example embodiments, the processor 110 may be understood as a chip (or an intellectual property) designed to control the operation of the semiconductor device 10B.

In addition, the system on chip 100B may include a plurality of input/output circuits 121, 122, 123, and 124 designed to transmit and receive data signals to and from the memory 200 and respectively provided on the second die 602, the third die 603, the fourth die 604, and the fifth die 605.

For example, the system on chip 100B may include a first input/output circuit 121 designed to transmit and receive data signals to and from the memory 200 and provided on the second die 602. In addition, the system on chip 100B may include a second input/output circuit 122 designed to transmit and receive data signals to and from the memory 200 and provided on the third die 603.

According to one or more example embodiments, the second die 602, the third die 603, the fourth die 604, and the fifth die 605 may be integrally provided. Accordingly, the plurality of input/output circuits 121, 122, 123, and 124 may be spaced apart from each other on the integrally provided die.

According to one or more example embodiments, each of the plurality of input/output circuits 121, 122, 123, and 124 may be understood as a chip (or an intellectual property) designed to transmit and receive data signals between the processor 110 and the memory 200.

For example, each of the processor 110 and the plurality of input/output circuits 121, 122, 123, and 124 may be referred to as a chiplet element designed and provided to perform a designated function thereof.

Each of the plurality of input/output circuits 121, 122, 123, and 124 may include a plurality of input/output elements connected to the processor 110. For example, each of the plurality of input/output circuits 121, 122, 123, and 124 may include a plurality of input/output elements arranged in a plurality of columns to be connected to the processor 110.

For example, the first input/output circuit 121 may include a first input/output element 211 provided in a first column r1 spaced apart from the processor 110 by a first distance. Also, the first input/output circuit 121 may include a second input/output element 212 provided in a second column r2 spaced apart from the processor 110 by a second distance, greater than the first distance.

Among the plurality of input/output elements included in the first input/output circuit 121, the input/output elements arranged in the second column r2 may be connected to the processor 110 through a region of the input/output elements arranged in the first column r1.

For example, the second input/output element 212 provided in the second column r2 may be connected to the processor 110 through a region of the first input/output element 211 provided in the first column r1.

Thus, the first input/output element 211 and the second input/output element 212 may be provided to abut each other without a gap. Furthermore, a plurality of input/output elements included in each of the plurality of input/output circuits 121, 122, 123, and 124 may be provided to abut each other without a gap.

According to one or more example embodiments, an electrical path connecting the processor 110 and the plurality of input/output elements to each other may be understood as a channel electrically connecting different chiplet elements to each other on the system on chip 100B.

According to the above-described configuration, the semiconductor device 10B according to one or more example embodiments may significantly reduce an area of the system on chip 100B while maintaining capacity of signals input and output by the system on chip 100B.

In addition, as described above, the semiconductor device 10B according to one or more example embodiments may provide the system on chip 100B including chips (for example, the processor 110 and the plurality of input/output circuits 121, 122, 123, and 124) designed to perform respective designated functions thereof.

Thus, the semiconductor device 10B according to one or more example embodiments may reduce a need consumed in a process for implementing the system on chip 100B.

As described above, in the system on chip according to one or more example embodiments, input/output elements provided in one column may be connected to a processor through an electrical path passing through a region of input/output elements provided in another column.

According to the above-described configuration, a plurality of input/output elements provided in different columns in the system on a chip may be provided to abut each other without a gap. In addition, in the system on chip, a plurality of input/output elements provided in the same column may be provided to abut each other without a gap.

Thus, the semiconductor device according to one or more example embodiments may significantly reduce an area of an input/output circuit (or a system on chip) using a plurality of input/output elements provided to abut each other without a gap.

The system on a chip according to one or more example embodiments may further include a power circuit having a width, smaller than or equal to a width of the input/output circuit, and provided adjacent to the input/output circuit.

Thus, the semiconductor device according to one or more example embodiments may significantly reduce an increase in area, caused by the power circuit. Furthermore, the semiconductor device according to one or more example embodiments may increase the degree of integration of the system on a chip.

A plurality of input/output elements, included in the system on chip according to one or more example embodiments, may be connected to a processor through a straight path.

Thus, the system on chip according to one or more example embodiments may prevent a signal from deteriorating due to detouring of an electrical path connecting an input/output element and the processor to each other.

In addition, the system on chip according to one or more example embodiments may significantly reduce an increase in area of the system on chip, caused by a wiring connecting the input/output element and the processor to each other.

As set forth above, a semiconductor device according to one or more example embodiments may include a plurality of input/output elements provided to abut each other without a gap to have a significantly reduced area.

While example embodiments have been particularly shown and described above, it will be apparent to those skilled in the art that various modifications and variations may be made without departing from the spirit and scope of the following claims.

What is claimed is:

1. A system on chip comprising:
a processor; and
an input and output circuit comprising a plurality of input and output elements connected to the processor,
wherein the plurality of input and output elements comprises:
a first input and output element spaced apart from the processor by a first distance; and
a second input and output element spaced apart from the processor by a second distance, greater than the first distance, and connected to the processor by a first electrical path extending through a first region of the first input and output element, and
wherein the first input and output element is connected to the processor by at least one first terminal provided in a second region that is separate from the first region.

2. The system on chip of claim 1, wherein the second input and output element comprises at least one second terminal provided in a portion adjacent to the first region, and
wherein the second input and output element is connected to the processor by the first electrical path which extends from the processor, through the first region, toward the at least one second terminal.

3. The system on chip of claim 1, wherein the plurality of input and output elements further comprises:
a third input and output element spaced apart from the processor by the first distance and provided to abut the first input and output element without a gap; and
a fourth input and output element spaced apart from the processor by the second distance and provided to abut the second input and output element and the third input and output element without a gap,
wherein the fourth input and output element is connected to the processor by a second electrical path extending through a third region of the third input and output element.

4. The system on chip of claim 1, wherein the first region of the first input and output element comprises a plurality of layers, and
wherein the second input and output element is connected to the processor by the first electrical path extending through a first layer, from among the plurality of layers of the first region.

5. The system on chip of claim 3, further comprising:
a power circuit spaced apart from the processor by a third distance, greater than the second distance, and adjacent to the input and output circuit,
wherein the power circuit is configured to supply power to at least a portion of the processor and the input and output circuit.

6. The system on chip of claim 5, wherein the power circuit has a width, equal to a width of the input and output circuit, and
wherein the power circuit is adjacent to one surface of the second input and output element and adjacent to one surface of the fourth input and output element.

7. The system on chip of claim 1, wherein the first input and output element further comprises a first contact provided in the second region, and
wherein the first input and output element is configured to:
transmit a signal, received by the first contact, to the processor, using the at least one first terminal; and
output a signal, received by the at least one first terminal, using the first contact.

8. The system on chip of claim 2, wherein the at least one first terminal and the at least one second terminal are provided to be symmetrical with respect to a virtual reference line crossing a center of the first input and output element and a center of the second input and output element.

9. A semiconductor device comprising:
a system on chip comprising a plurality of input and output elements provided in a plurality of columns; and
a memory mounted on an interposer and connected to the system on chip using the interposer,
wherein the system on chip comprises:
a processor;
a first input and output element provided in a first column spaced apart from the processor by a first distance; and
a second input and output element adjacent to the first input and output element in a second column spaced apart from the processor by a second distance, greater than the first distance, and connected to the processor by a first electrical path extending through a first region of the first input and output element, and
wherein the first input and output element is connected to the processor by at least one first terminal provided in a second region that is separate from the first region.

10. The semiconductor device of claim 9, wherein the second input and output element comprises at least one second terminal provided in a portion adjacent to the first region, and
wherein the second input and output element is connected to the processor by the first electrical path which extends from the processor, through the first region, toward the at least one second terminal.

11. The semiconductor device of claim 9, wherein the first input and output element and the second input and output element are configured to:
transmit a signal, received from the processor, to the memory, using the interposer; and
transmit a signal, received from the memory, to the processor, using the interposer.

12. The semiconductor device of claim 9, wherein the system on chip further comprises:
a third input and output element provided, in the first column, to abut the first input and output element without a gap; and
a fourth input and output element provided to abut the second input and output element and the third input and output element without a gap,
wherein the fourth input and output element is connected to the processor by a second electrical path extending through a third region of the third input and output element.

13. The semiconductor device of claim 9, wherein the first region of the first input and output element comprises a plurality of layers, and
wherein the second input and output element is connected to the processor by the first electrical path extending through a first layer, from among the plurality of layers of the first region.

14. The semiconductor device of claim 9, wherein the second region has a second width that is smaller than or equal to a first width of the first region.

15. The semiconductor device of claim 12, wherein the system on chip further comprises:
a power circuit adjacent to input and output elements provided in the second column,
wherein the power circuit is provided in a third column spaced apart from the processor by a third distance that is greater than the second distance, and
wherein the power circuit is configured to supply power to at least a portion of the processor, the first input and output element, and the second input and output element.

16. The semiconductor device of claim 9, wherein each of the first input and output element and the second input and output element comprises a structure that is symmetrical with respect to a virtual reference line crossing a center of the first input and output element and a center of the second input and output element.

17. An input and output circuit comprising a plurality of input and output elements, the plurality of input and output elements comprising:
a first input and output element comprising at least one first terminal; and
a second input and output element adjacent to the first input and output element,
wherein the first input and output element comprises:
a first region comprising a first electrical path connected to the second input and output element; and
a second region that is separate from the first region, the second region comprising the at least one first terminal, and
wherein the second input and output element comprises at least one second terminal provided at a point adjacent to the first region to be connected to the first electrical path.

18. The input and output circuit of claim 17, wherein the first electrical path extends toward the at least one second terminal through the first region.

19. The input and output circuit of claim 17, further comprising:
a third input and output element provided to abut the first input and output element without a gap; and
a fourth input and output element provided to abut the second input and output element and the third input and output element without any gaps,
wherein the fourth input and output element is connected to a second electrical path extending by a third region of the third input and output element.

20. The input and output circuit of claim 17, wherein the first region of the first input and output element comprises a plurality of layers, and
wherein the second input and output element is connected to the first electrical path extending through a first layer, from among the plurality of layers of the first region.
